(19) United States
(12) Patent Application Publication
(10) Pub. No.: US 2012/0154992 A1
(43) Pub. Date: Jun. 21, 2012

(54) ELECTRONIC DEVICE

(75) Inventor: HAI-QING ZHOU, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/980,310

(22) Filed: Dec. 28, 2010

(30) Foreign Application Priority Data
Dec. 17, 2010 (CN) 201010594359.8

(51) Int. Cl. H05K 7/00

(52) U.S. Cl. 361/679.01

(57) ABSTRACT

An electronic device includes a shell, and a wire holder. The wire holder includes a plate mounted to an outer side of the shell, and a number of arc-shaped latches extending out from the plate, to hold cables of peripheral connectors.

### BACKGROUND

1. Technical Field

The present disclosure relates generally to electronic devices, and particularly to an electronic device with a wire holder.

2. Description of Related Art

A plurality of connector interfaces is mounted to a rear end of an electronic device, for being electrically connected to a plurality of peripheral connectors. However, when the connectors are detached from the connector interfaces, the connectors are often disorderly piled up. It is troublesome to sort out the connectors for next use.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is a partial, assembled, isometric view of an embodiment of an electronic device together with a plurality of peripheral connectors.

FIG. 2 is an exploded, isometric view of the electronic device of FIG. 1, the electronic device includes a shell and a wire holder.

FIG. 3 is an enlarged view of the wire holder of FIG. 2, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

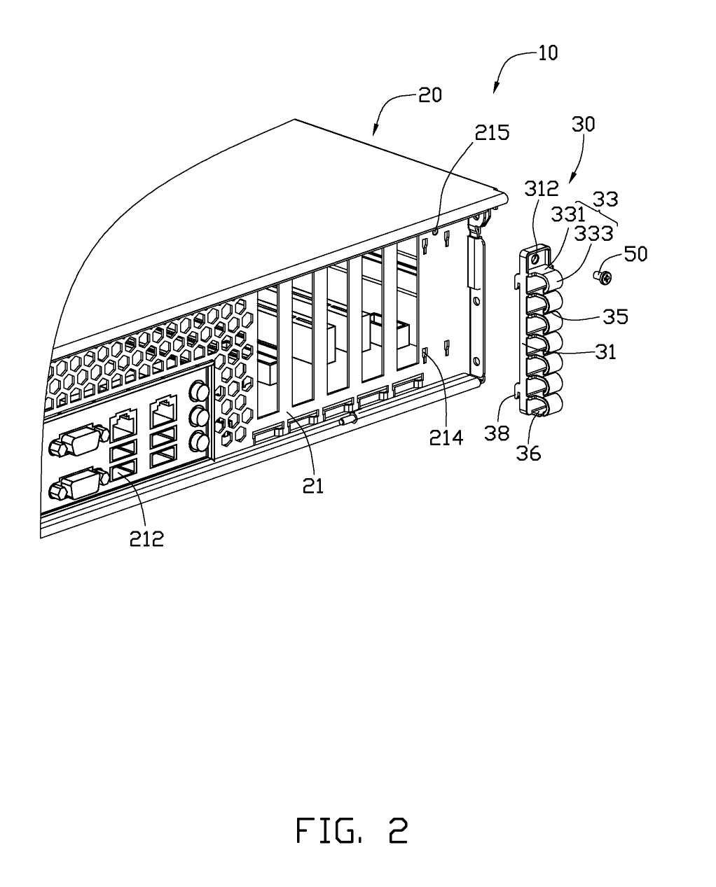

Referring to FIG. 2, an embodiment of an electronic device 10 includes a shell 20, and a wire holder 30.

The shell 20 includes a rear wall 21. A plurality of connector interfaces 212 is mounted to the rear wall 21. Two pairs of hooking slots 214 and a fixing hole 215 are defined in the rear wall 21 adjacent to an end of the rear wall 21.

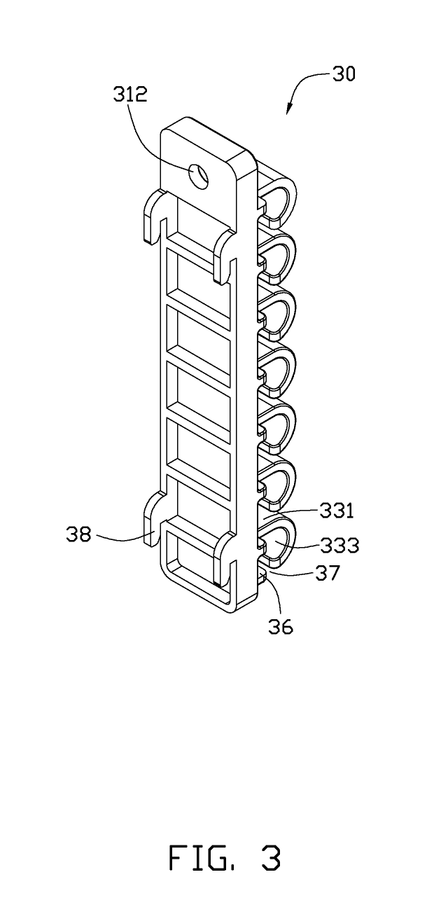

Referring to FIG. 3, the wire holder 30 includes an elongated plate 31, and a plurality of latches 33 protruding from a first side of the plate 31. The latches 33 are arranged lengthwise. Each latch 33 includes a supporting portion 331 substantially perpendicularly extending from the first side of the plate 31, and a resilient arc-shaped latching portion 333 extending towards a first end of the plate 31 from a distal end of the supporting portion 331. A narrow slot 35 is bound by a distal end of each latching portion 333 and an adjacent latch 33, which is near to the first end of the plate 31. A stop plate 36 substantially perpendicularly extends from the first side of the plate 31 adjacent to the first end of the plate 31. The stop plate 36 aligns with the distal end of the latching portion 333 of a latch 33, which is closest to the first end of the plate 31. The stop plate 36 and the distal end of the latching portion 333 bind a narrow slot 37. A through hole 312 is defined in the plate 31 adjacent to a second end of the plate 31 opposite to the first end. Two pairs of hooks 38 extend from a second side of the plate 31 opposite to the first side. In this embodiment, the latches 33 are made of plastic materials.

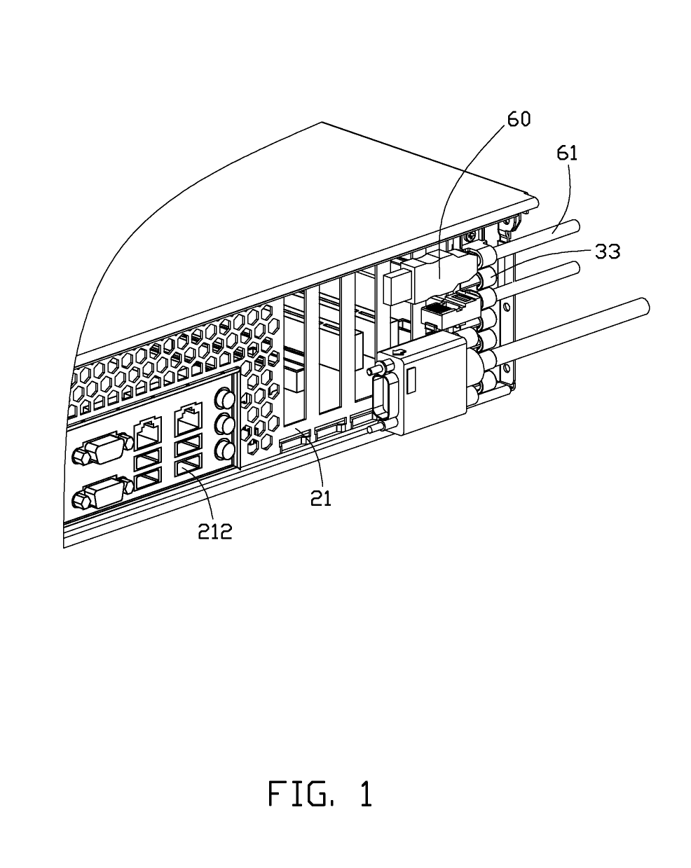

Referring to FIG. 1, in assembly, the hooks 38 of the wire holder 30 are engaged in the corresponding hooking slots 214 of the shell 20. A screw 50 is extended through the through hole 312 of the wire holder 30 and engages in the fixing hole 215 of the shell 20. Thereby, the wire holder 30 is fixed to an outer side of the rear wall 21 of the shell 20.

To hold a plurality of peripheral connectors 60 each including a cable 61, the cables 61 are pressed towards the corresponding latches 33 from the slots 35 and 37. The latching portions 333 of the latches 33 are deformed to expand the slots 35 and 37, thereby allowing the corresponding cables 61 to enter the latches 33. The latching portions 333 of the latches 33 are restored to shrink the slots 35 and 37 thereby the latches 33 hold the corresponding cables 61 therein. The cables 61 of the connectors 60 are slidable in the latches 33. When the connectors 60 are detached from the corresponding connector interfaces 212 of the shell 20, the cables 61 are still held by the corresponding latches 33. It is convenient to an operator to find out desired connectors 60 for next use.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. An electronic device, comprising:
a shell; and
a wire holder comprising a plate mounted to an outer side of the shell, and a plurality of latches extending out from the plate to hold wires.

2. The electronic device of claim 1, wherein the plate is elongated, and the latches are arranged lengthwise on the plate.

3. The electronic device of claim 2, wherein each of the latches comprises a supporting portion substantially perpendicularly extending from the plate, and a resilient arc-shaped latching portion extending towards a first end of the plate from a distal end of the supporting portion.

4. The electronic device of claim 3, wherein a narrow slot is bound by a distal end of each latching portion and an adjacent latch near the first end of the plate.

5. The electronic device of claim 3, wherein a stop plate substantially perpendicularly extends from the plate, the stop plate aligns with the distal end of the latching portion of one of the latches closest to the first end of the plate.

6. The electronic device of claim 5, wherein a narrow slot is bound by the stop plate and the distal end of the latching portion of the latch closest to the first end of the plate.

7. The electronic device of claim 1, wherein the shell comprises a rear wall with a plurality of connector interfaces, the wire holder is mounted to the rear wall.

8. The electronic device of claim 7, wherein two pairs of hooking slots are defined in the rear wall, two pairs of hooks extend from the plate of the wire holder opposite to the latches, to engage in the corresponding hooking slots.

9. The electronic device of claim 8, wherein a fixing hole is defined in the rear wall, a through hole is defined in the plate of the wire holder, a screw is extended through the through hole of the wire holder and engages in the fixing hole of the rear wall.

10. The electronic device of claim 1, wherein the latches are made of plastic materials.
